(19) United States
(12) Patent Application Publication
(10) Pub. No.: US 2017/0357911 A1
(43) Pub. Date: Dec. 14, 2017

(54) FEATURE SEARCH BY MACHINE LEARNING

(71) Applicant: ASML Netherlands B.V., Veldhoven (NL)

(72) Inventors: Xiaofeng LIU, Campbell, CA (US); Yen-Wen LU, Saratoga, CA (US)

(73) Assignee: ASML Netherlands B.V., Veldhoven (NL)

(21) Appl. No.: 15/531,321

(22) PCT Filed: Nov. 18, 2015
(86) PCT No.: PCT/EP2015/076994

§ 371 Date: May 26, 2017

Related U.S. Application Data
(60) Provisional application No. 62/093,931, filed on Dec. 18, 2014.

(51) Int. Cl. G06N 99/00; G03F 7/20; G06F 17/50

(52) U.S. Cl. CPC G06N 99/005; G06F 17/5068; G06F 17/5081; G03F 7/70

(57) ABSTRACT

A method to improve a lithographic process for imaging a portion of a design layout onto a substrate using a lithographic projection apparatus, the method including: obtaining a target feature; generating a perturbed target feature from the target feature by applying a perturbation thereto; generating a set of training examples includes the perturbed target feature and an indication as whether the perturbed target feature is deemed the same as the target feature; training a learning model with the set of training examples; classifying features in the portion of the design layout into at least two classes: being deemed the same as the target feature, and being deemed different from the target feature.

### CROSS-REFERENCE TO RELATED APPLICATIONS

This application claims priority of U.S. application 62/093,931 which was filed on Dec. 18, 2014 and which is incorporated herein in its entirety by reference.

### TECHNICAL FIELD

The description herein relates to lithographic apparatuses and processes, and more particularly to a method or tool for searching for matches to a target feature.

### BACKGROUND

A lithographic projection apparatus can be used, for example, in the manufacture of integrated circuits (ICs). In such a case, a patterning device (e.g., a mask) may contain or provide a circuit pattern corresponding to an individual layer of the IC (“design layout”), and this circuit pattern can be transferred onto a target portion (e.g. comprising one or more dies) on a substrate (e.g., silicon wafer) that has been coated with a layer of radiation-sensitive material (“resist”), by methods such as irradiating the target portion through the circuit pattern on the patterning device. In general, a single substrate contains a plurality of adjacent target portions to which the circuit pattern is transferred successively by the lithographic projection apparatus, one target portion at a time. In one type of lithographic projection apparatuses, the circuit pattern on the entire patterning device is transferred onto one target portion in one go; such an apparatus is commonly referred to as a wafer stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the circuit pattern on the patterning device are transferred to one target portion progressively. Since, in general, the lithographic projection apparatus will have a magnification factor M (generally <1), the speed F at which the substrate is moved will be a factor M times that at which the projection beam scans the patterning device. More information with regard to lithographic devices as described herein can be gleaned, for example, from U.S. Pat. No. 6,046,792, incorporated herein by reference.

Prior to transferring the circuit pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred circuit pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

As noted, microlithography is a central step in the manufacturing of ICs, where patterns formed on substrates define functional elements of the ICs, such as microprocessors, memory chips etc. Similar lithographic techniques are also used in the formation of flat panel displays, micro-electro mechanical systems (MEMS) and other devices.

### SUMMARY

Disclosed herein is a computer-implemented method to improve a lithographic process for imaging a portion of a design layout onto a substrate using a lithographic projection apparatus, the method comprising: obtaining a target feature; generating a perturbed target feature from the target feature by applying a perturbation thereto; generating a set of training examples comprising the perturbed target feature and an indication as whether the perturbed target feature is deemed same as the target feature; training a learning model with the set of training examples; classifying, by a computer, features in the portion of the design layout into at least two classes: being deemed same as the target feature, and being deemed different from the target feature.

Also disclosed herein is a computer program product comprising a non-transitory computer readable medium having information recorded thereon, wherein information comprising a target feature, one or more perturbed target feature, an indication of whether the one or more perturbed target feature is deemed same as the target feature.

Further disclosed herein is a computer program product comprising a computer readable medium having information recorded thereon, wherein information comprising a target feature and a machine learning model configured to classify a feature into two classes: being deemed same as the target feature, and being deemed different from the target feature.

### BRIEF DESCRIPTION OF THE DRAWINGS

The above aspects and other aspects and features will become apparent to those ordinarily skilled in the art upon review of the following description of specific embodiments in conjunction with the accompanying figures, wherein:

FIG. 1 is a block diagram of various subsystems of a lithography system according to an embodiment;

FIG. 2 is a block diagram of simulation models corresponding to the subsystems in FIG. 1;

FIG. 3 shows a flow chart for a method of searching for features that are similar to a target feature, using a machine learning model, according to an embodiment;

FIG. 4 schematically shows applying a low pass filter to a plurality of features 410 to obtain a pixilated image of the features;

FIG. 5 schematically shows a flow chart of generating a training set and using the training set to train a machine learning model;

FIG. 6 schematically shows that the training set preferably includes a plurality of perturbed target features that are the same as the target feature except being shifted in various directions by various amounts relative to a window;

FIG. 7 schematically shows searching for matches of the target feature in a large image which has many features, using a machine learning model for the target feature;

FIG. 8 schematically shows the multi-resolution feature searching method using three machine learning models for the same target feature but at different resolutions;

FIG. 9 schematically shows one application for any of the feature searching methods;

FIG. 10 is a block diagram of an example computer system in which embodiments can be implemented;

FIG. 11 is a schematic diagram of another lithographic projection apparatus;

FIG. 12 is a more detailed view of the apparatus in FIG. 11;

FIG. 13 is a more detailed view of the source collector module SO of the apparatus of FIG. 11 and FIG. 12.

### DETAILED DESCRIPTION

Embodiments will now be described in detail with reference to the drawings, which are provided as illustrative examples so as to enable those skilled in the art to practice the embodiments. Notably, the figures and examples below are not meant to limit the scope to a single embodiment, but other embodiments are possible by way of interchange of some or all of the described or illustrated elements. Wherever convenient, the same reference numbers will be used throughout the drawings to refer to same or like parts. Where certain elements of these embodiments can be partially or fully implemented using known components, only those portions of such known components that are necessary for an understanding of the embodiments will be described, and detailed descriptions of other portions of such known components will be omitted so as not to obscure the description of the embodiments. In the present specification, an embodiment showing a singular component should not be considered limiting; rather, the scope is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the scope encompasses present and future known equivalents to the components referred to herein by way of illustration.

As semiconductor manufacturing processes continue to advance, the dimensions of functional elements have continually been reduced while the amount of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a circuit designer in order to achieve particular electrical functionality and performance. To overcome these difficulties, sophisticated fine-tuning steps are applied to the lithographic projection apparatus and/or design layout. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

As an example, OPC addresses the fact that the final size and placement of an image of the design layout projected on the substrate will not be identical to, or simply depend only on the size and placement of the design layout on the patterning device. It is noted that the terms “mask”, “reticle”, “patterning device” are utilized interchangeably herein. Also, person skilled in the art will recognize that, especially in the context of lithography simulation/optimization, the term “mask,” “patterning device” and “design layout” can be used interchangeably, as in lithography simulation/optimization, a physical patterning device is not necessarily used but a design layout can be used to represent a physical patterning device. For the small feature sizes and high feature densities present on some design layout, the position of a particular edge of a given feature will be influenced to a certain extent by the presence or absence of other adjacent features. These proximity effects arise from minute amounts of radiation coupled from one feature to another and/or non-geometrical optical effects such as diffraction and interference. Similarly, proximity effects may arise from diffusion and other chemical effects during post-exposure bake (PEB), resist development, and etching that generally follow lithography.

In order to ensure that the projected image of the design layout is in accordance with requirements of a given target circuit design, proximity effects need to be predicted and compensated for, using sophisticated numerical models, corrections or pre-distortions of the design layout. The article “Full-Chip Lithography Simulation and Design Analysis—How OPC Is Changing IC Design”, C. Spence, Proc. SPIE, Vol. 5751, pp 1-14 (2005) provides an overview of current “model-based” optical proximity correction processes. In a typical high-end design almost every feature of the design layout has some modification in order to achieve high fidelity of the projected image to the target design. These modifications may include shifting or biasing of edge positions or line widths as well as application of “assist” features that are intended to assist projection of other features.

Application of model-based OPC to a target design involves good process models and considerable computational resources, given the many millions of features typically present in a chip design. However, applying OPC is generally not an exact science, but an empirical, iterative process that does not always compensate for all possible proximity effect. Therefore, effect of OPC, e.g., design layouts after application of OPC and any other RET, need to be verified by design inspection, i.e. intensive full-chip simulation using calibrated numerical process models, in order to minimize the possibility of design flaws being built into the patterning device pattern. This is driven by the enormous cost of making high-end patterning devices, which run in the multi-million dollar range, as well as by the impact on turn-around time by reworking or repairing actual patterning devices once they have been manufactured.

Both OPC and full-chip RET verification may be based on numerical modeling systems and methods as described, for example in, U.S. patent application Ser. No. 10/815,573 and an article titled “Optimized Hardware and Software For Fast, Full Chip Simulation”, by Y. Cao et al., Proc. SPIE, Vol. 5754, 405 (2005).

One RET is related to adjustment of the global bias of the design layout. The global bias is the difference between the patterns in the design layout and the patterns intended to print on the substrate. For example, a circular pattern of 25 nm diameter may be printed on the substrate by a 50 nm diameter pattern in the design layout or by a 20 nm diameter pattern in the design layout but with high dose.

In addition to optimization to design layouts or patterning devices (e.g., OPC), the illumination source can also be optimized, either jointly with patterning device optimization or separately, in an effort to improve the overall lithography fidelity. The terms “illumination source” and “source” are used interchangeably in this document. Since the 1990s, many off-axis illumination sources, such as annular, quadrupole, and dipole, have been introduced, and have provided more freedom for OPC design, thereby improving the imaging results, As is known, off-axis illumination is a proven way to resolve fine structures (i.e., target features) contained in the patterning device. However, when compared to a traditional illumination source, an off-axis illumination source usually provides less radiation intensity for the aerial image (AI). Thus, it becomes desirable to attempt to optimize the illumination source to achieve the optimal balance between finer resolution and reduced radiation intensity.

Numerous illumination source optimization approaches can be found, for example, in an article by Rosenbluth et al., titled “Optimum Mask and Source Patterns to Print A Given Shape”, Journal of Microlithography, Microfabrication, Microsystems 1(1), pp. 13-20, (2002). The source is partitioned into several regions, each of which corresponds to a certain region of the pupil spectrum. Then, the source distribution is assumed to be uniform in each source region and the brightness of each region is optimized for process window. However, such an assumption that the source distribution is uniform in each source region is not always valid, and as a result the effectiveness of this approach suffers. In another example set forth in an article by Granik, titled “Source Optimization for Image Fidelity and Throughput”, Journal of Microlithography, Microfabrication, Microsystems 3(4), pp. 509-522, (2004), several existing source optimization approaches are overviewed and a method based on illuminator pixels is proposed that converts the source optimization problem into a series of non-negative least square optimizations. Though these methods have demonstrated some successes, they typically require multiple complicated iterations to converge. In addition, it may be difficult to determine the appropriate/optimal values for some extra parameters, such as γ in Granik's method, which dictates the trade-off between optimizing the source for substrate image fidelity and the smoothness requirement of the source.

For low k₁ photolithography, optimization of both the source and patterning device is useful to ensure a viable process window for projection of critical circuit patterns. Some algorithms (e.g. Socha et. al. Proc. SPIE vol. 5853, 2005, p. 180) discretize illumination into independent source points and mask into diffraction orders in the spatial frequency domain, and separately formulate a cost function (which is defined as a function of selected design variables) based on process window metrics such as exposure latitude which could be predicted by optical imaging models from source point intensities and patterning device diffraction orders. The term “design variables” as used herein comprises a set of parameters of a lithographic projection apparatus, for example, parameters a user of the lithographic projection apparatus can adjust. It should be appreciated that any characteristics of a lithographic projection process, including those of the source, the patterning device, the projection optics, and/or resist characteristics can be among the design variables in the optimization. The cost function is often a non-linear function of the design variables. Then standard optimization techniques are used to minimize the cost function.

Relatedly, the pressure of ever decreasing design rules have driven semiconductor chipmakers to move deeper into the low k₁ lithography era with existing 193 nm ArF lithography. Lithography towards lower k₁ puts heavy demands on RET, exposure tools, and the need for litho-friendly design. 1.35 ArF hyper numerical aperture (NA) exposure tools may be used in the future. To help ensure that circuit design can be produced on to the substrate with workable process window, source-patterning device optimization (referred to herein as source-mask optimization or SMO) is becoming a significant RET for 2× nm node.

A source and patterning device (design layout) optimization method and system that allows for simultaneous optimization of the source and patterning device using a cost function without constraints and within a practicable amount of time is described in a commonly assigned International Patent Application No. PCT/US2009/065359, filed on Nov. 20, 2009, and published as WO2010/059954, titled “Fast Freeform Source and Mask Co-Optimization Method”, which is hereby incorporated by reference in its entirety.

Another source and patterning device optimization method and system that involves optimizing the source by adjusting pixels of the source is described in a commonly assigned U.S. patent application Ser. No. 12/813,456, filed on Jun. 10, 2010, and published as U.S. Patent Application Publication No. 2010/0315614, titled “Source-Mask Optimization in Lithographic Apparatus”, which is hereby incorporated by reference in its entirety.

Although specific reference may be made in this text to the use of the embodiments in the manufacture of ICs, it should be explicitly understood that the embodiments has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle,” “wafer” or “die” in this text should be considered as interchangeable with the more general terms “mask,” “substrate” and “target portion,” respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range 5-20 nm).

The term “optimizing” and “optimization” as used herein mean adjusting a lithographic projection apparatus such that results and/or processes of lithography have more desirable characteristics, such as higher accuracy of projection of design layouts on a substrate, larger process windows, etc.

Further, the lithographic projection apparatus may be of a type having two or more substrate tables (and/or two or more patterning device tables). In such “multiple stage” devices the additional tables may be used in parallel, or preparatory steps may be carried out on one or more tables while one or more other tables are being used for exposures. Twin stage lithographic projection apparatuses are described, for example, in U.S. Pat. No. 5,969,441, incorporated herein by reference.

The patterning device referred to above comprise design layouts. The design layouts can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between circuit devices (such as gates, capacitors, etc.) or interconnect lines, so as to ensure that the circuit devices or lines do not interact with one another in an undesirable way. The design rule limitations are typically referred to as “critical dimensions” (CD). A critical dimension of a circuit can be defined as the smallest width of a line or hole or the smallest space between two lines or two holes. Thus, the CD determines the overall size and density of the designed circuit. One of the goals in integrated circuit fabrication is to faithfully reproduce the original circuit design on the substrate (via the patterning device).

The term patterning device as employed in this text may be broadly interpreted as referring to generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The matrix addressing can be performed using suitable electronics. More information on such mirror arrays can be gleaned, for example, from U.S. Pat. Nos. 5,296,891 and 5,523,193, which are incorporated herein by reference.
a programmable LCD array. An example of such a construction is given in U.S. Pat. No. 5,229,872, which is incorporated herein by reference.

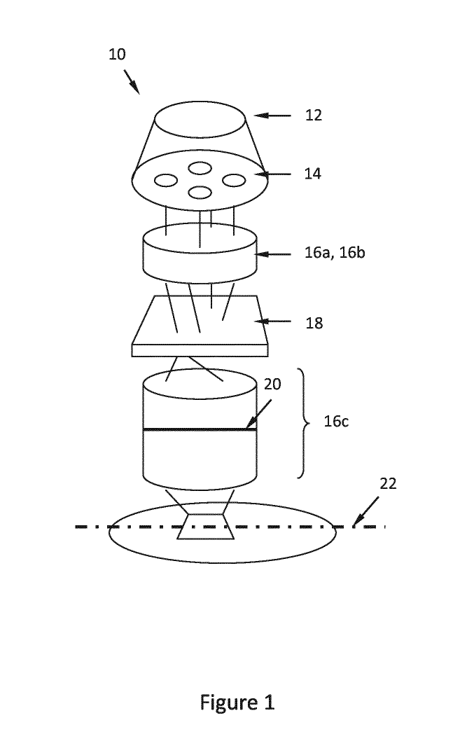

As a brief introduction, FIG. 1 illustrates an exemplary lithographic projection apparatus 10. Major components are an illumination source 12, which may be a deep-ultraviolet excimer laser source or other type of sources including extreme ultra violet (EUV) sources, illumination optics which define the partial coherence (denoted as sigma) and which may include optics 14, 16a and 16b that shape radiation from the source 12; a patterning device (e.g., a mask or reticle) 18; and transmission optics 16c that project an image of the patterning device pattern onto a substrate plane 22. An adjustable filter or aperture 20 at the pupil plane of the projection optics may restrict the range of beam angles that impinge on the substrate plane 22, where the largest possible angle defines the numerical aperture of the projection optics NA=sin(Θₘₐₓ).

In an optimization process of a system, a figure of merit of the system can be represented as a cost function. The optimization process boils down to a process of finding a set of parameters (design variables) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics; the cost function can also be the maximum of these deviations. The term “evaluation points” herein should be interpreted broadly to include any characteristics of the system. The design variables of the system can be confined to finite ranges and/or be interdependent due to practicalities of implementations of the system. In case of a lithographic projection apparatus, the constraints are often associated with physical properties and characteristics of the hardware such as tunable ranges, and/or patterning device manufacturability design rules, and the evaluation points can include physical points on a resist image on a substrate, as well as non-physical characteristics such as dose and focus.

In a lithographic projection apparatus, a source provides illumination (i.e. radiation); projection optics direct and shapes the illumination via a patterning device and onto a substrate. The term “projection optics” is broadly defined here to include any optical component that may alter the wavefront of the radiation beam. For example, projection optics may include at least some of the components 14, 16a, 16b and 16c. An aerial image (AI) is the radiation intensity distribution on the substrate. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in commonly assigned U.S. patent application Ser. No. 12/315,849, disclosure of which is hereby incorporated by reference in its entirety. The resist model is related only to properties of the resist layer (e.g., effects of chemical processes which occur during exposure, PEB and development). Optical properties of the lithographic projection apparatus (e.g., properties of the source, the patterning device and the projection optics) dictate the aerial image. Since the patterning device used in the lithographic projection apparatus can be changed, it is desirable to separate the optical properties of the patterning device from the optical properties of the rest of the lithographic projection apparatus including at least the source and the projection optics.

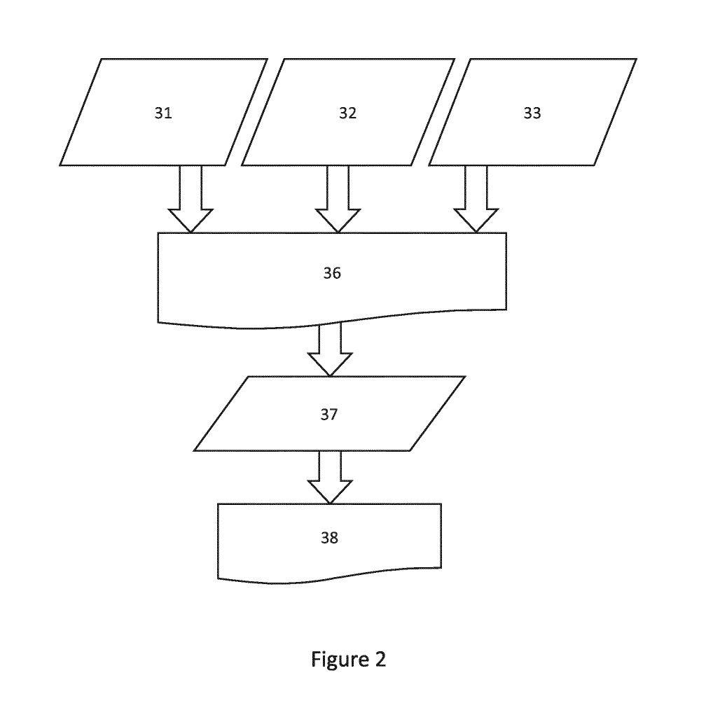

An exemplary flow chart for simulating lithography in a lithographic projection apparatus is illustrated in FIG. 2. A source model 31 represents optical characteristics (including radiation intensity distribution and/or phase distribution) of the source. A projection optics model 32 represents optical characteristics (including changes to the radiation intensity distribution and/or the phase distribution caused by the projection optics) of the projection optics. The projection optics model 32 may include aberration caused by various factors, for example, heating of the components of the projection optics, stress caused by mechanical connections of the components of the projection optics. The source model 31 and the projection optics model 32 can be combined into a transmission cross coefficient (TCC) model. A design layout model 33 represents optical characteristics (including changes to the radiation intensity distribution and/or the phase distribution caused by a given design layout) of a design layout, which is the representation of an arrangement of features of a patterning device. An aerial image 36 can be simulated from the source model 31, the projection optics model 32 and the design layout model 33. A resist image 38 can be simulated from the aerial image 36 using a resist model 37. Simulation of lithography can, for example, predict contours and CDs in the resist image.

More specifically, it is noted that the source model 31 can represent the optical characteristics of the source that include, but not limited to, NA-sigma (σ) settings as well as any particular illumination source shape (e.g. off-axis radiation sources such as annular, quadrupole, and dipole, etc.). The projection optics model 32 can represent the optical characteristics of the of the projection optics that include aberration, distortion, refractive indexes, physical sizes, physical dimensions, absorption, etc. The design layout model 33 can also represent physical properties of a physical patterning device, as described, for example, in U.S. Pat. No. 7,587,704, which is incorporated by reference in its entirety. The objective of the simulation is to accurately predict, for example, edge placements and CDs, which can then be compared against an intended design. The intended design is generally defined as a pre-OPC design layout which can be provided in a standardized digital file format such as GDSII or OASIS or other file format.

From this design layout, one or more portions may be identified, which are referred to as “clips.” In a specific embodiment, a set of clips is extracted, which represents the complicated patterns in the design layout (typically about 50 to 1000 clips, although any number of clips may be used). As will be appreciated by those skilled in the art, these patterns or clips represent small portions (i.e. circuits, cells or patterns) of the design and especially the clips represent small portions for which particular attention and/or verification is needed. In other words, clips may be the portions of the design layout or may be similar or have a similar behavior of portions of the design layout where critical features are identified either by experience (including clips provided by a customer), by trial and error, or by running a full-chip simulation. Clips usually contain one or more test patterns or gauge patterns.

An initial larger set of clips may be provided a priori by a customer based on known critical feature areas in a design layout which require particular image optimization. Alternatively, in another embodiment, the initial larger set of clips may be extracted from the entire design layout by using some kind of automated (such as, machine vision) or manual algorithm that identifies the critical feature areas.

Examples of optimization methods can be found, for example, in U.S. patent application Ser. No. 12/914,946 filed Oct. 28, 2010, the disclosure of which is hereby incorporated by reference in its entirety.

As the sizes of features on a design layout shrink, OPC can become more time consuming. A library containing features that are very difficult to correct by OPC and their OPC correction may be used to reduce the cost of OPC if a feature search method allows finding similar features on the design layout of those features in the library. The OPC correction of those features in the library can then be simply applied to the similar feature without or with very little further computation. Such a feature search method is preferably very fast, able to tolerate certain degrees of differences between the features in the library and those similar features. A feature search method is certainly not limited to this particular application but can be useful in many others.

A machine learning model is a useful tool that may prove useful in a feature search method. Both unsupervised machine learning and supervised machine learning models may be used. Without limiting the scope of the claims, applications of supervised machine learning models in the context of feature search are described below.

Supervised learning is the machine learning task of inferring a function from labeled training data. The training data consist of a set of training examples. In supervised learning, each example is a pair consisting of an input object (typically a vector) and a desired output value (also called the supervisory signal). A supervised learning algorithm analyzes the training data and produces an inferred function, which can be used for mapping new examples. An optimal scenario will allow the algorithm to correctly determine the class labels for unseen instances. This requires the learning algorithm to generalize from the training data to unseen situations in a “reasonable” way (see inductive bias).

Given a set of N training examples of the form {(x₁,y₁), (x₂,y₂), . . . , (x_{N},y_{N})} such that xᵢ is the feature vector of the i-th example and yᵢ is its label (i.e., class), a learning algorithm seeks a function g: X→Y, where X is the input space and Y is the output space. A feature vector is an n-dimensional vector of numerical features that represent some object. Many algorithms in machine learning require a numerical representation of objects, since such representations facilitate processing and statistical analysis. When representing images, the feature values might correspond to the pixels of an image, when representing texts perhaps term occurrence frequencies. The vector space associated with these vectors is often called the feature space. The function g is an element of some space of possible functions G, usually called the hypothesis space. It is sometimes convenient to represent g using a scoring function f: X×Y→ [symbol] such that g is defined as returning the y value that gives the highest score: g(x)=arg max_{y} f(x,y). Let F denote the space of scoring functions.

Although G and F can be any space of functions, many learning algorithms are probabilistic models where g takes the form of a conditional probability model g(x)=P(y|x), or f takes the form of a joint probability model f(x,y)=P(x,y). For example, naive Bayes and linear discriminant analysis are joint probability models, whereas logistic regression is a conditional probability model.

There are two basic approaches to choosing f or g: empirical risk minimization and structural risk minimization. Empirical risk minimization seeks the function that best fits the training data. Structural risk minimize includes a penalty function that controls the bias/variance tradeoff.

In both cases, it is assumed that the training set consists of a sample of independent and identically distributed pairs, (xᵢ,yᵢ). In order to measure how well a function fits the training data, a loss function L: Y×Y→ [symbol] ^{≧0} is defined. For training example (xᵢ,yᵢ), the loss of predicting the value ŷ is L(yᵢ,ŷ).

The risk R(g) of function g is defined as the expected loss of g. This can be estimated from the training data as

$${R}_{emp} ( g ) = \frac{1}{N} {\sum }_{i} L ( {y}_{i} , g ( {x}_{i} ) ) .$$

Exemplary models of supervised learning include Decision trees, Ensembles (Bagging, Boosting, Random forest), k-NN, Linear regression, Naive Bayes, Neural networks, Logistic regression, Perceptron, Support vector machine (SVM), Relevance vector machine (RVM), and deep learning.

SVM is an example of supervised learning model, which analyzes data and recognize patterns and can be used for classification and regression analysis. Given a set of training examples, each marked as belonging to one of two categories, an SVM training algorithm builds a model that assigns new examples into one category or the other, making it a non-probabilistic binary linear classifier. An SVM model is a representation of the examples as points in space, mapped so that the examples of the separate categories are divided by a clear gap that is as wide as possible. New examples are then mapped into that same space and predicted to belong to a category based on which side of the gap they fall on.

In addition to performing linear classification, SVMs can efficiently perform a non-linear classification using what is called the kernel methods, implicitly mapping their inputs into high-dimensional feature spaces.

Kernel methods require only a user-specified kernel, i.e., a similarity function over pairs of data points in raw representation. Kernel methods owe their name to the use of kernel functions, which enable them to operate in a high-dimensional, implicit feature space without ever computing the coordinates of the data in that space, but rather by simply computing the inner products between the images of all pairs of data in the feature space. This operation is often computationally cheaper than the explicit computation of the coordinates. This approach is called the “kernel trick.”

The effectiveness of SVM depends on the selection of kernel (linear or non-linear), the kernel's parameters, and soft margin parameter C. A common choice is a Gaussian radial basis kernel, which has a single parameter γ. The best combination of C and γ is often selected by a grid search (also known as “parameter sweep”) with exponentially growing sequences of C and γ, for example, Cε{2⁻⁵; 2⁻⁴; . . . ; 2¹⁵, 2¹⁶}; γε{2⁻¹⁵; 2⁻¹⁴ . . . ; 2⁴; 2⁵}. Another choice is a histogram intersection kernel.

A grid search is an exhaustive searching through a manually specified subset of the hyperparameter space of a learning algorithm. A grid search algorithm must be guided by some performance metric, typically measured by cross-validation on the training set or evaluation on a held-out validation set.

Each combination of parameter choices may be checked using cross validation, and the parameters with best cross-validation accuracy are picked.

Cross-validation, sometimes called rotation estimation, is a model validation technique for assessing how the results of a statistical analysis will generalize to an independent data set. It is mainly used in settings where the goal is prediction, and one wants to estimate how accurately a predictive model will perform in practice. In a prediction problem, a model is usually given a dataset of known data on which training is run (training dataset), and a dataset of unknown data (or first seen data) against which the model is tested (testing dataset). The goal of cross validation is to define a dataset to “test” the model in the training phase (i.e., the validation dataset), in order to limit problems like overfitting, give an insight on how the model will generalize to an independent data set (i.e., an unknown dataset, for instance from a real problem), etc. One round of cross-validation involves partitioning a sample of data into complementary subsets, performing the analysis on one subset (called the training set), and validating the analysis on the other subset (called the validation set or testing set). To reduce variability, multiple rounds of cross-validation are performed using different partitions, and the validation results are averaged over the rounds.

The final model, which is used for testing and for classifying new data, is then trained on the whole training set using the selected parameters.

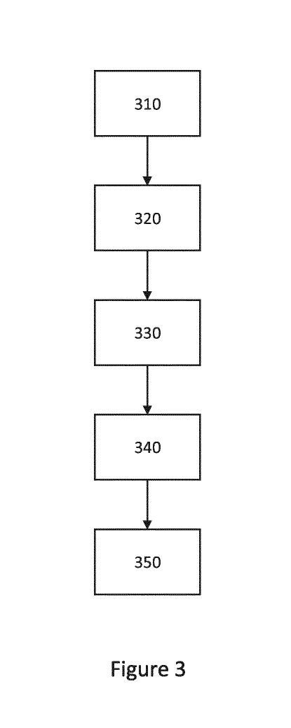

FIG. 3 shows a flow chart for a method of searching for features that are similar to a target feature, using a machine learning model, according to an embodiment. In step 310, the target feature is obtained. The target feature may be inputted by a user, selected using an algorithm (e.g., a hot spot, a feature difficult to correct by OPC, etc.), selected from a library, or obtained by any suitable methods.

In step 320, one or more perturbed target features are generated from the target feature by applying one or more perturbations thereto. For example, the perturbations can include scaling, skewing, shifting, rotating, warping, distorting, flipping, removing a portion thereof, adding a portion thereof, etc.

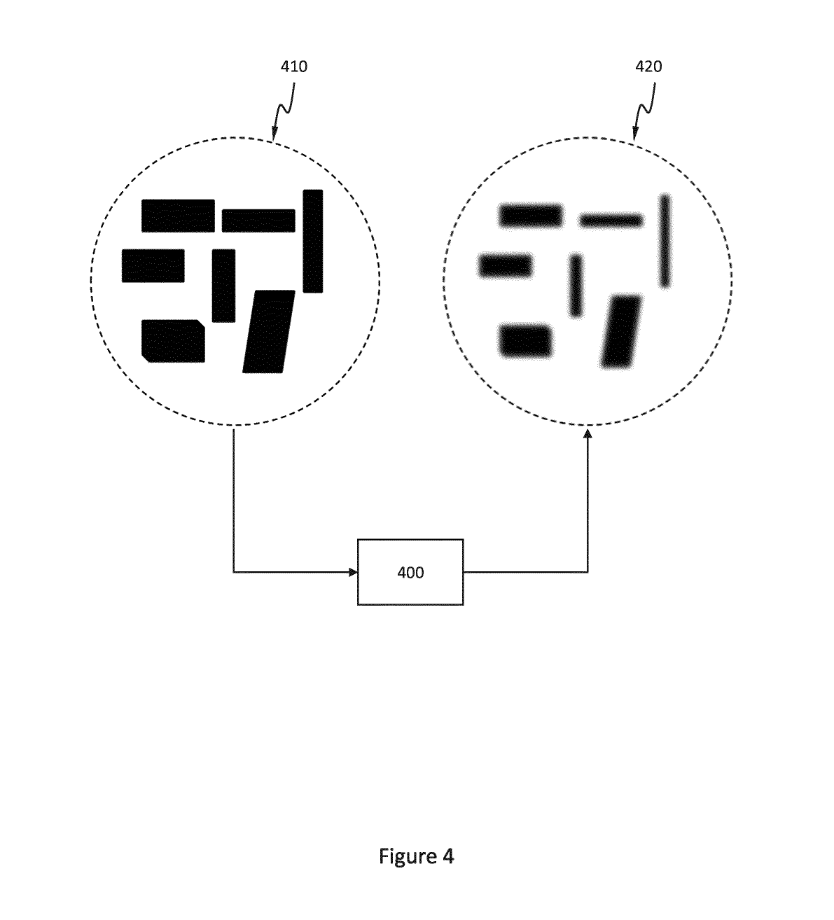

In step 330, a set of training examples (“training set”) is generated comprising feature vectors of characteristics of the perturbed target features and an indication as whether the perturbed target features are deemed same as the target feature. The characteristics of a feature may be obtained by a method of parameterization. The characteristics may be any suitable characteristics. In a very simple example, the characteristics may include the number of vertices or edges, the area, the orientation, the relative positions of the vertices, etc. In an embodiment, the characteristics of the features may be obtained from one or more pixelated images at various resolutions of the features. A pixilated image of a feature may be obtained by applying a low pass filter to the feature. FIG. 4 schematically shows applying a low pass filter 400 to a plurality of features 410 to obtain a pixilated image 420 of the features 410. The indication is the class of the feature vectors. For example, there may be only two classes—one class “m” for those deemed the same as the target feature and one class “um” for those deemed different from the target feature. There could be more than two classes.

In step 340, a supervised learning model is trained with the training set.

In step 350, the supervised learning model may be used to determine whether a feature, using the characteristics thereof, is deemed the same as or different from that target feature—classifying a feature into at least two classes: being deemed same as the target feature, and being deemed different from the target feature.

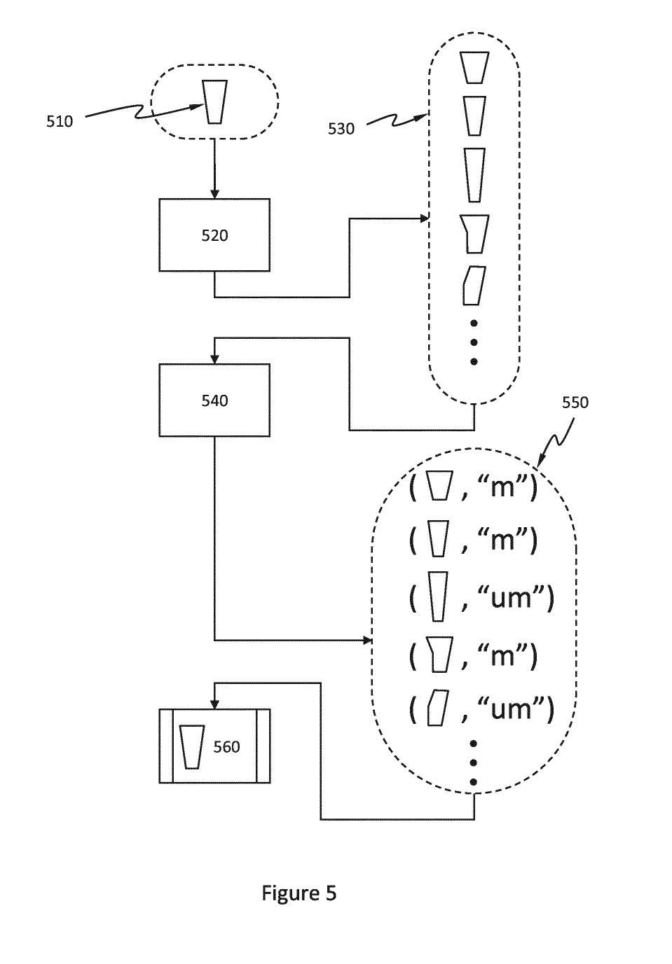

FIG. 5 schematically shows a flow chart of generating a training set and using the training set to train a machine learning model. A target feature 510 is first obtained and undergoes a perturbation step 520 that generate a set of one or more perturbed target features 530. In step 540, the one or more perturbed target features 530 are assigned an indication as to whether the perturbed target features 530 are deemed the same as or different from the target feature 510 (in this example, “m” means being deemed the same; “um” means being deemed different) and compiled into the training set 550 that has one or more element each of which has a feature vector representing the characteristics of the one or more perturbed target features 530 and the indication. The training set is then used to train a machine learning model 560 that determines whether a feature is the same (in the class of “m”) as or different (in the class of “um”) from the target feature 510.

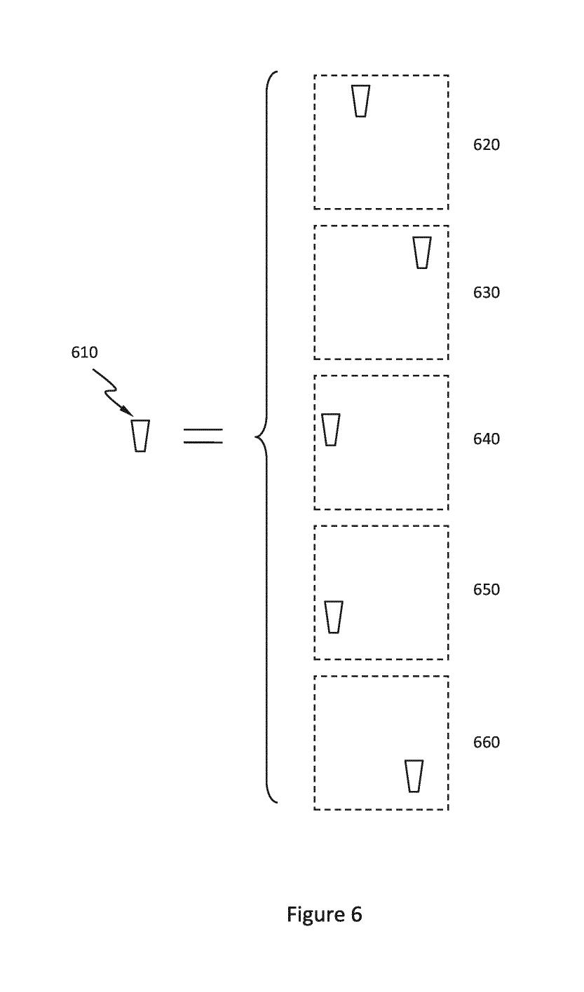

As schematically shown in FIG. 6, the training set preferably includes a plurality of perturbed target features 620-660 that are the same as the target feature 610 except being shifted in various directions by various amounts relative to a “window”—an image area. These perturbed target features all belong to the class of “m.” Including these shifted target features allows searching for matches of the target feature 610 at a faster pace through a large image.

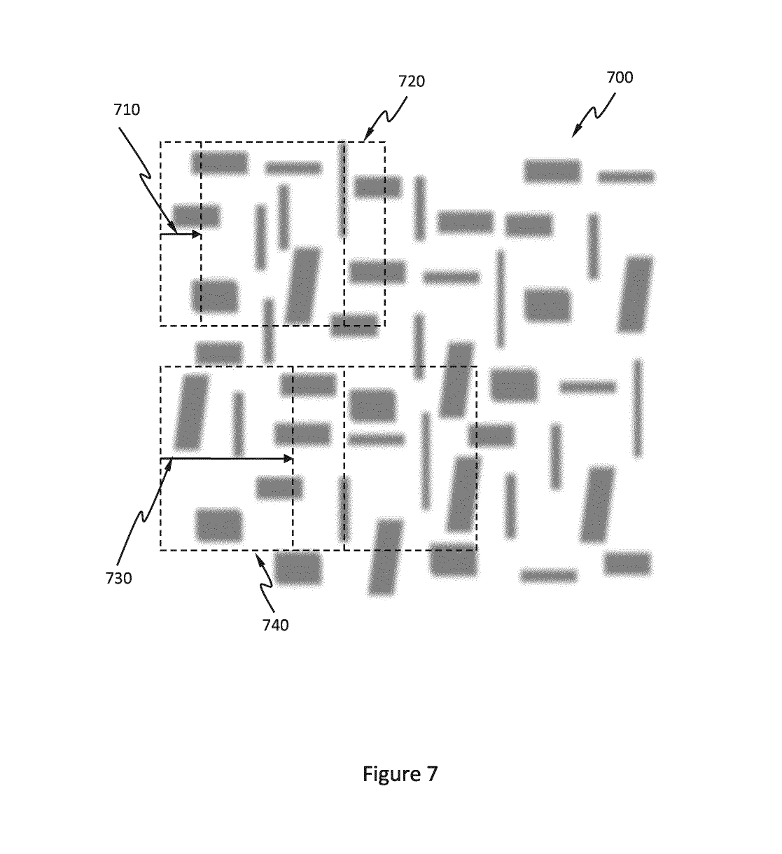

FIG. 7 schematically shows searching for matches of the target feature in a large image 700 which has many features, using a machine learning model for the target feature. The process of searching for matches of the target feature in the large image 700 essentially involves using the machine learning model to determine whether a portion of the image 700 within the window contains a match to the target feature and sliding the window to a next location. If the machine learning model is trained with a training set that includes perturbed target features that are the same as the target feature except being shifted by an amount 710, the machine learning model will allow “sliding” the window 720 by that amount 710. Similarly, if the machine learning model is trained with a training set that includes perturbed target features that are the same as the target feature except being shifted by an amount 730 (larger than amount 710), the machine learning model will allow “sliding” the window 740 by that amount 730, which leads to faster search.

A given target feature may have multiple machine learning models trained for different situations. In an embodiment, a training set (e.g., 550) for a target feature (e.g., 510) may be pixilated at different resolutions (e.g., by applying different low pass filters) to obtain multiple training sets. Each of these multiple training sets can be used to train a machine learning model for searching matches to the same target feature but at those different resolutions. Searching at a lower resolution is generally faster but less accurate than searching at a higher resolution. Therefore, a multi-resolution feature searching method may be implemented using these machine learning models.

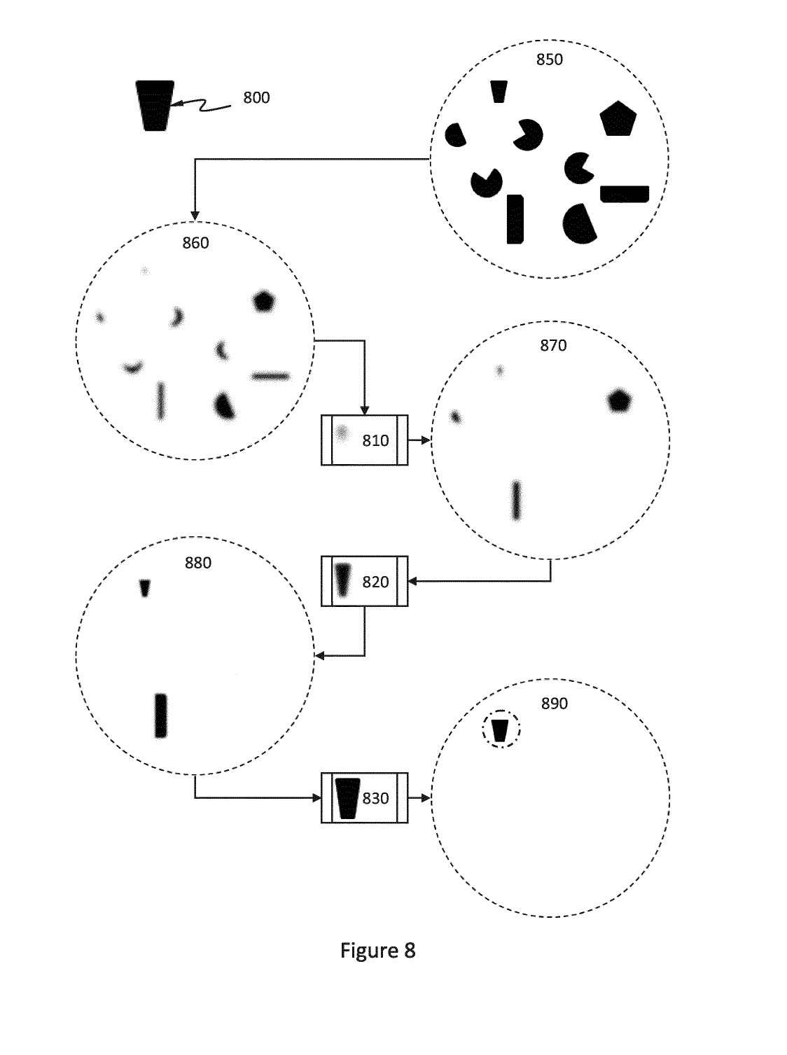

FIG. 8 schematically shows the multi-resolution feature searching method using three machine learning models 810-830 for the same target feature 800 but at different resolutions.

The machine learning model 810 is at a lower resolution than the machine learning model 820, which is at a lower resolution than the machine learning model 830. The different degrees of blurring of the target feature 800 in the boxes depicting the machine learning models 810-830 schematically indicate their respectively resolution. In this example, matches of (i.e., those feature deemed the same as) the target feature 800 are being searched for in a group of features 850. First, a first pixilated image 860 at the resolution of the machine learning model 810 is obtained, by, e.g., applying a first low pass filter to the group of features 850. The pixilated image 860 is searched using the machine learning model 810 and only the matches determined by the machine learning model 810 are kept, from which a second pixilated image 870 at the resolution of the machine learning model 820 is obtained, by, e.g., applying a second low pass filter to the matches. The pixilated image 870 is searched using the machine learning model 820 and only the matches determined by the machine learning model 820 are kept, from which a third pixilated image 880 at the resolution of the machine learning model 830 is obtained, by, e.g., applying a third low pass filter to the matches. The pixilated image 880 is searched using the machine learning model 830 and only the matches determined by the machine learning model 830 are deemed as final matches to the target feature 800. This multi-resolution feature searching method is much faster than searching through all the features 850 at the resolution of the machine learning model 830. Preferably, the resolution of the machine learning model 830 is two or more times higher than the resolution of the machine learning model 820; the resolution of the machine learning model 820 is two or more times higher than the resolution of the machine learning model 810.

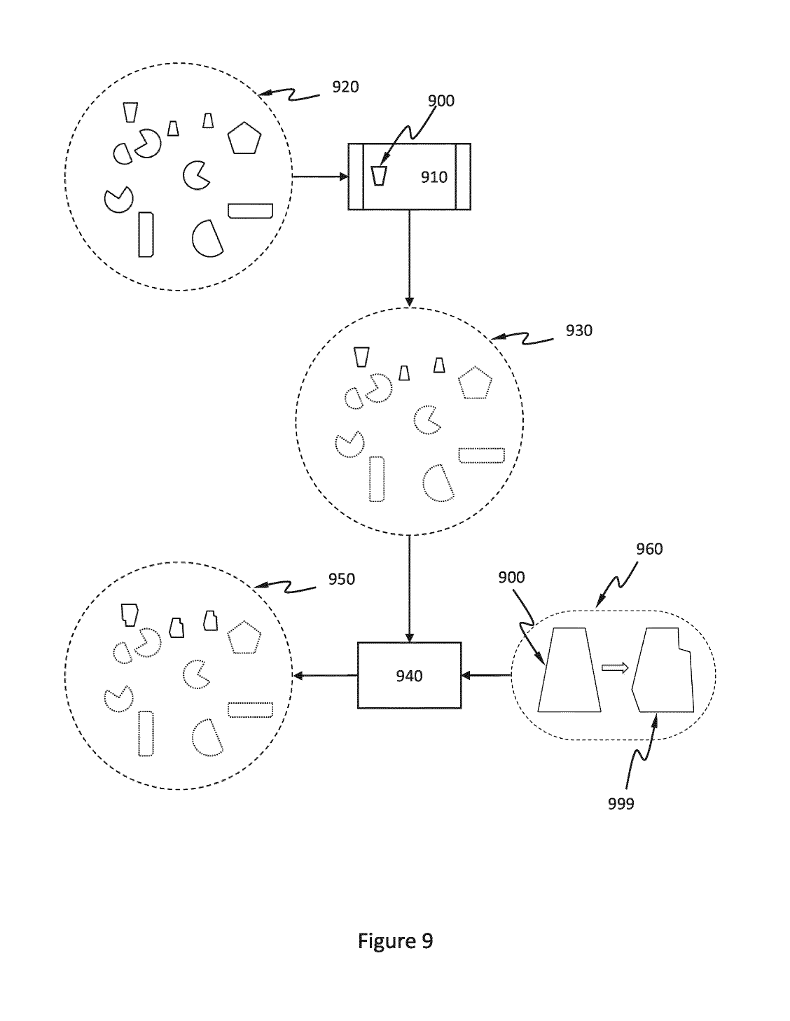

FIG. 9 schematically shows one application for any of the feature searching methods described above. A machine learning model 910 for a target feature 900 is obtained. The machine learning model 910 searches a group of patterns 920 for matches of the target feature 900. In this example, three matches are found (those in solid line). The matches are represented in solid line in group 930. A library 960 containing a recipe for the target feature 900 is obtained.

The recipe can be, for example, an OPC correction 999 for the target feature 900, a processing condition (e.g., dose, defocus, etc.) for the target feature 900. The recipe for the target feature 900 is then applied to the three matches in a step 940. Group 950 schematically shows that the three matches have the recipe applied thereto.

A library may be compiled to comprise a target feature, and a training set for that target feature. The training set may include one or more perturbed target features, indication of whether the one or more perturbed target features are deemed same as the target feature.

A library may be compiled to comprise a target feature and a machine learning model for the target feature.

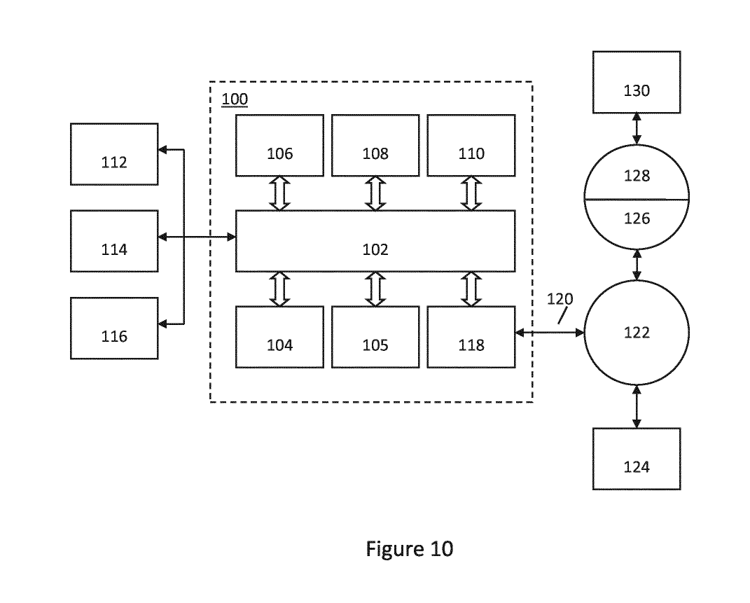

FIG. 10 is a block diagram that illustrates a computer system 100 which can assist in implementing the feature searching methods and flows disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the optimization process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In alternative embodiments, hard-wired circuitry may be used in place of or in combination with software instructions. Thus, embodiments are not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may also include a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. In accordance with one or more embodiments, one such downloaded application provides for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

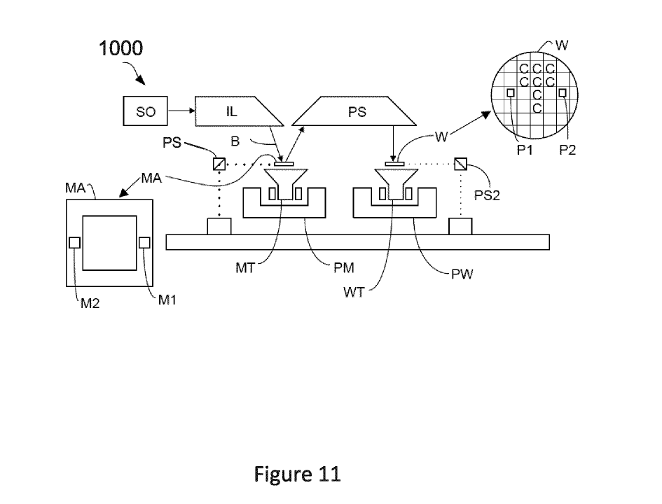

FIG. 11 schematically depicts another exemplary lithographic projection apparatus 1000 whose illumination source could be optimized utilizing the methods described herein.

The lithographic projection apparatus 1000 includes:
a source collector module SO
an illumination system (illuminator) IL configured to condition a radiation beam B (e.g. EUV radiation).
a support structure (e.g. a mask table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

As here depicted, the apparatus 1000 is of a reflective type (e.g. employing a reflective mask). It is to be noted that because most materials are absorptive within the EUV wavelength range, the mask may have multilayer reflectors comprising, for example, a multi-stack of Molybdenum and Silicon. In one example, the multi-stack reflector has a 40 layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 11, the illuminator IL receives an extreme ultra violet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 11, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus 1000 could be used in at least one of the following modes:

1. In step mode, the support structure (e.g. mask table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

2. In scan mode, the support structure (e.g. mask table) MT and the substrate table WT are scanned synchronously while a pattern imparted to the radiation beam is projected onto a target portion C (i.e. a single dynamic exposure). The velocity and direction of the substrate table WT relative to the support structure (e.g. mask table) MT may be determined by the (de-) magnification and image reversal characteristics of the projection system PS.

3. In another mode, the support structure (e.g. mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

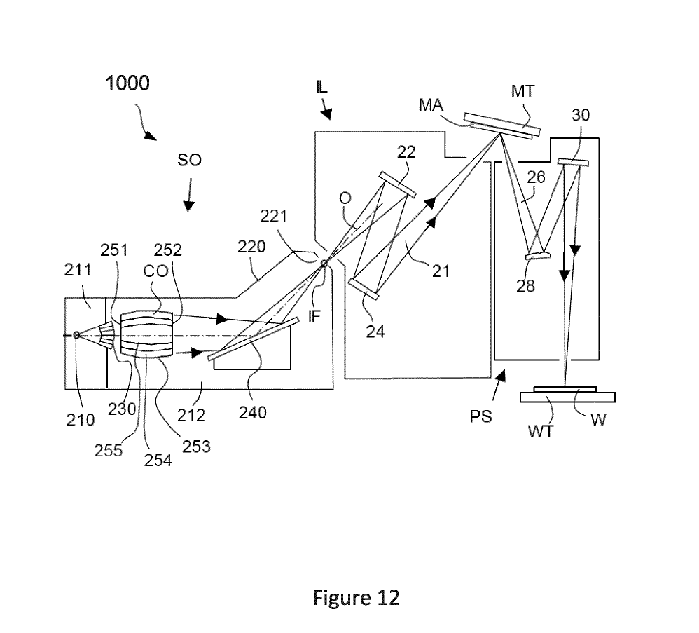

FIG. 12 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘0’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 12.

Collector optic CO, as illustrated in FIG. 12, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type is preferably used in combination with a discharge produced plasma source, often called a DPP source.

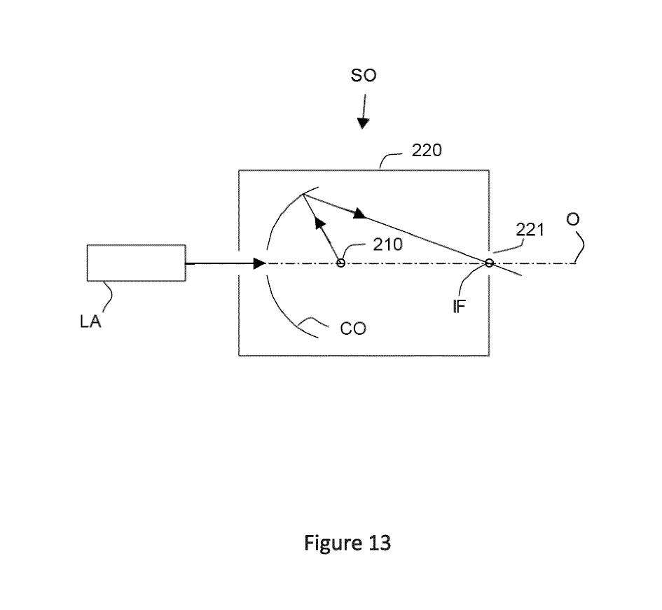

Alternatively, the source collector module SO may be part of an LPP radiation system as shown in FIG. 13. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing wavelengths of an increasingly smaller size. Emerging technologies already in use include EUV (extreme ultra violet) lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The invention may further be described using the following clauses:

1. A computer-implemented method to improve a lithographic process for imaging a portion of a design layout onto a substrate using a lithographic projection apparatus, the method comprising:

obtaining a target feature;

generating a perturbed target feature from the target feature by applying a perturbation thereto;

generating a set of training examples comprising the perturbed target feature and an indication as whether the perturbed target feature is deemed same as the target feature;

training a learning model with the set of training examples;

classifying, by a computer, features in the portion of the design layout into at least two classes: being deemed same as the target feature, and being deemed different from the target feature.

2. The method of clause 1, wherein classifying the features is based on a first pixelated image of the features, the first pixelated image having a first resolution.
3. The method of clause 2, further comprising generating the first pixelated image by applying a low pass filter to the features.
4. The method of clause 1, wherein the perturbation is resizing, shifting, removing a portion of, adding a portion to the target feature, or a combination thereof.
5. The method of clause 1, wherein the learning model is non-probabilistic.
6. The method of clause 1, wherein the learning model is a support vector machine.
7. The method of clause 1, wherein the learning model has a non-linear kernel.
8. The method of clause 1, wherein the supervised learning model has a Gaussian radial basis kernel or a histogram intersection kernel.
9. The method of clause 2, wherein classifying the features comprises classifying a portion of the first pixelated image in a sliding window.
10. The method of clause 9, further comprising shifting the sliding window.
11. The method of clause 10, wherein the perturbation is shifting the target feature, wherein the sliding window is shifted by an amount equal to or smaller than an amount of shifting in the perturbation.
12. The method of clause 2, wherein classifying the features is further based on a second pixelated image of the features, the second pixelated image having a second resolution higher than the first resolution.
13. The method of clause 12, wherein the second resolution is two or more times higher than the first resolution.
14. The method of clause 1, wherein classifying the features comprises geometrically parameterizing the features and the target feature.
15. The method of clause 1, further comprising applying an adjustment of the target feature to those of the features classified as being deemed same as the target feature.
16. The method of any of clauses 1 to 15, wherein the machine learning model is a supervised machine learning model.
17. A computer program product comprising a non-transitory computer readable medium having instructions recorded thereon, the instructions when executed by a computer implementing the method of any of the above clauses.
18. A computer program product comprising a non-transitory computer readable medium having information recorded thereon, wherein information comprising a target feature, one or more perturbed target feature, and optionally an indication of whether the one or more perturbed target feature is deemed same as the target feature.
19. The computer program product of clause 18, further comprising an adjustment of the target feature.
20. The computer program product of clause 19, wherein the adjustment comprises optical proximity correction.
21. A computer program product comprising a computer readable medium having information recorded thereon, wherein information comprising a target feature and a machine learning model configured to classify a feature into two classes: being deemed same as the target feature, and being deemed different from the target feature.
22. A computer-implemented feature recognition method for a device manufacturing process involving processing a portion of a design layout onto a substrate, the method comprising:

obtaining a target feature;

generating perturbed target features from the target feature by applying a perturbation thereto;

generating a set of training examples comprising the perturbed target features and an indication as whether the perturbed target features are deemed same as the target feature;

training a learning model with the set of training examples;

classifying, by a computer, features in the portion of the design layout into two classes: being deemed same as the target feature, and being deemed different from the target feature.

23. The method of clause 22, wherein classifying the features is based on a first pixelated image of the features, the first pixelated image having a first resolution, wherein classifying the features is further based on a second pixelated image of the features, the second pixelated image having a second resolution higher than the first resolution.
24. The method of clause 22, wherein the learning model has a non-linear kernel.
25. The method of clause 22, wherein classifying the features comprises classifying a portion of the first pixelated image in a sliding window.
26. The method of clause 25, further comprising shifting the sliding window.
27. The method of clause 26, wherein the perturbation is shifting the target feature, wherein the sliding window is shifted by an amount equal to or smaller than an amount of shifting in the perturbation.

Aspects of the invention can be implemented in any convenient form. For example, an embodiment may be implemented by one or more appropriate computer programs which may be carried on an appropriate carrier medium which may be a tangible carrier medium (e.g. a disk) or an intangible carrier medium (e.g. a communications signal). Embodiments of the invention may be implemented using suitable apparatus which may specifically take the form of a programmable computer running a computer program arranged to implement a method as described herein.

The descriptions above are intended to be illustrative, not limiting. Thus, it will be apparent to one skilled in the art that modifications may be made to the embodiments as described without departing from the scope of the claims set out below.

1. A method to improve a process involving imaging a portion of a design layout onto a substrate using a lithographic projection apparatus, the method comprising:
generating a perturbed target feature from a target feature by applying a perturbation thereto;
generating a set of training examples comprising the perturbed target feature and an indication as whether the perturbed target feature is deemed the same as the target feature;
training a learning model with the set of training examples; and
classifying, by a hardware computer, features in the portion of the design layout into at least two classes: being deemed the same as the target feature, and being deemed different from the target feature.

2. The method of claim 1, wherein classifying the features is based on a first pixelated image of the features, the first pixelated image having a first resolution.

3. The method of claim 2, further comprising generating the first pixelated image by applying a low pass filter to the features.

4. The method of claim 1, wherein the perturbation is resizing, shifting, removing a portion of, adding a portion to the target feature, or any combination selected therefrom.

5. The method of claim 1, wherein the learning model is non-probabilistic, or wherein the learning model is a support vector machine, or wherein the learning model has a non-linear kernel.

6. The method of claim 1, wherein the learning model has a Gaussian radial basis kernel or a histogram intersection kernel.

7. The method of claim 2, wherein classifying the features comprises classifying a portion of the first pixelated image in a sliding window.

8. The method of claim 7, further comprising shifting the sliding window.

9. The method of claim 8, wherein the perturbation is shifting the target feature, and wherein the sliding window is shifted by an amount equal to or smaller than an amount of shifting in the perturbation.

10. The method of claim 2, wherein classifying the features is further based on a second pixelated image of the features, the second pixelated image having a second resolution higher than the first resolution.

11. The method of claim 1, wherein classifying the features comprises geometrically parameterizing the features and the target feature.

12. The method of claim 1, further comprising applying an adjustment of the target feature to those of the features classified as being deemed the same as the target feature.

13. A non-transitory computer program product comprising a computer readable medium having instructions recorded thereon, the instructions configured to cause a computer to:
generate a perturbed target feature from a target feature by applying a perturbation thereto;
generate a set of training examples comprising the perturbed target feature and an indication as whether the perturbed target feature is deemed the same as the target feature;
train a learning model with the set of training examples; and
classify features in the portion of the design layout into at least two classes: being deemed the same as the target feature, and being deemed different from the target feature.

14. A feature recognition method for a device manufacturing process involving processing a portion of a design layout onto a substrate, the method comprising:
generating perturbed target features from a target feature by applying a perturbation thereto;
generating a set of training examples comprising the perturbed target features and an indication as whether the perturbed target features are deemed the same as the target feature;
training a learning model with the set of training examples; and
classifying, by a computer, features in the portion of the design layout into two classes: being deemed the same as the target feature, and being deemed different from the target feature.

15. The method of claim 14, wherein classifying the features comprises classifying a portion of a pixelated image in a sliding window.

16. The method of claim 14, wherein classifying the features is based on a first pixelated image of the features, the first pixelated image having a first resolution.

17. The method of claim 16, wherein classifying the features is further based on a second pixelated image of the features, the second pixelated image having a second resolution higher than the first resolution.

18. The method of claim 14, wherein the perturbation is resizing, shifting, removing a portion of, adding a portion to the target feature, or any combination selected therefrom.

19. The method of claim 14, wherein classifying the features comprises geometrically parameterizing the features and the target feature.

20. The method of claim 14, further comprising applying an adjustment of the target feature to those of the features classified as being deemed the same as the target feature.
